(19) United States
(12) Patent Application Publication
(10) Pub. No.: US 2009/0163037 A1
(43) Pub. Date: Jun. 25, 2009

(54) MANUFACTURING METHOD OF SEMICONDUCTOR DEVICE AND SUBSTRATE PROCESSING APPARATUS

(75) Inventors: Hironobu Miya, Tokyo (JP); Jie Wang, Toyama-shi (JP)

Correspondence Address: MATTINGLY & MALUR, P.C., 1800 DIAGONAL ROAD, SUITE 370, ALEXANDRIA, VA, 22314, US

(73) Assignee: Hitachi-Kokusai Electric Inc.

(21) Appl. No.: 12/269,443

(22) Filed: Nov. 12, 2008

(30) Foreign Application Priority Data
Nov. 13, 2007 (JP) 2007-293955

(51) Int. Cl. H01L 21/31; C23C 16/54

(52) U.S. Cl. 438/778; 118/715; 257/E21.24

(57) ABSTRACT

Provided is a substrate processing apparatus which is capable of suppressing the erosion of a metal member installed inside the processing chamber. The substrate processing apparatus includes: a processing chamber for performing a processing of forming a high dielectric constant film on a substrate; a processing gas supply system for supplying a processing gas into the processing chamber in order to form the high dielectric constant film; and a cleaning gas supply system for supplying a cleaning gas, which comprises a halogen-based gas except for a fluorine-based gas, into the processing chamber in order to remove materials including the high dielectric constant film deposited on the inside of the processing chamber, wherein a metal member is installed inside the processing chamber, and a DLC film is formed on at least a part of a surface of the metal member where the cleaning gas contacts.

### CROSS-REFERENCE TO RELATED PATENT APPLICATION

This U.S. non-provisional patent application claims priority under 35 U.S.C. § 119 of Japanese Patent Application No. 2007-293955, filed on Nov. 13, 2007, in the Japanese Patent Office, the entire contents of which are hereby incorporated by reference.

### BACKGROUND OF THE INVENTION

1. Field of the Invention

The present invention relates to a manufacturing method of a semiconductor device and a substrate processing apparatus.

2. Description of the Prior Art

In semiconductor devices such as a DRAM which is getting denser, a high dielectric constant film (high dielectric constant insulation film) is used as a gate dielectric film or a capacitor dielectric film in order to suppress a gate leakage current at a thin gate dielectric film and increase the capacitance of a capacitor.

Formation of high dielectric constant films should satisfy the following requirements: films should be formed at a low temperature, surfaces of films should be flat, step coverage and filling characteristics with respect to underlying concave-convex parts should be excellent, and foreign particles should not be introduced into the films. High dielectric constant films are formed by supplying a processing gas into a processing chamber where a substrate is loaded. When forming the high dielectric constant films, materials including high dielectric constant films may be deposited on the inner wall of the processing chamber or on members such as a substrate holder installed in the processing chamber, and the deposited materials are susceptible to be peeled off from the inner wall of the processing chamber and contaminate the high dielectric constant films. Therefore, in order to suppress the contamination caused by foreign particles, whenever a film made of deposited materials reaches a predetermined thickness, the inside of the processing chamber or members installed in the processing chamber should be cleaned by removing the deposited materials by etching.

As for methods of etching deposited materials, there are a wet etching method where a reaction tube constituting the processing chamber is removed and immersion etching is performed using a cleaning solution, and a dry etching method where an excited etching gas is supplied into the processing chamber. Recently, the dry etching method without removing the reaction tube has been utilized. As the dry etching method, there is a method of exciting an etching gas by plasma or heat. The former is often utilized for a single wafer type apparatus for the uniformity of plasma density and easy control of a bias voltage, and the latter is often utilized for a batch and vertical type apparatus. In particular, studies have been actively conducted on a dry etching method using a halogen-based gas which is excited by plasma. The non-patent document 1 discloses the etching of an HfO₂ film by BCl₃/N₂ plasma, the non-patent document 2 discloses the etching of an HfO₂ film and a ZrO₂ film by BCl₃/Cl₂ plasma, and the non-patent documents 3 and 4 disclose the etching of an HfO₂ film by BCl₃/O₂ plasma. Furthermore, the patent documents 1 to 3 disclose the etching using BCl₃.

[Non-patent Document 1] K. J. Nordheden and J. F. Sia, J. Appl. Phys., Vol. 94, (2003) 2199

[Non-patent Document 2] Sha. L., Chang. P. J., J. Vac. Sci. Technol. A22 (1), (2004) 88

[Non-patent Document 3] Kitagawa Tomohiro, Ono Kouichi, Oosawa Masanori, Hasaka Satoshi, Inoue Minoru, Taiyo Nippon Sanso Technology Journal No. 24 (2005)

[Non-patent Document 4] T. Kitagawa, K. Nakamura, K. Osari, K. Takahashi, K. Ono, M. Oosawa, S. Hasaka, M. Inoue: Jpn. J. Appl. Phys. 45 (10), L297-L300 (2006)

[Patent Document 1] Japanese Patent Publication No. 2004-146787

[Patent Document 2] Japanese Patent Publication No. 2006-179834

[Patent Document 3] Japanese Patent Publication No. 2006-339523

However, in the above-mentioned dry etching method, a surface of a metal member installed in the processing chamber may be eroded during etching of deposited materials. When the surface of the metal member is eroded, the metal contamination may occur on a substrate or in the processing chamber, which may lead to decrease in the film quality of the high dielectric constant film and lead to degradation in properties, yield or reliability of devices.

In order to suppress the erosion of the surface of the metal member, a metal oxide film or a metal fluoride film for prevention of the metal contamination may be formed in advance on the surface of the metal member. However, even though the metal oxide film or the metal fluoride film is formed, if a gas including a halogen-based gas such as BCl₃ is used as a cleaning gas, it may be impossible to expect enough effects to prevent the metal contamination.

### SUMMARY OF THE INVENTION

Therefore, an object of the present invention is to provide a substrate processing apparatus and a manufacturing method of a semiconductor device which are capable of suppressing the erosion of a metal member installed in a processing chamber.

According to an aspect of the present invention, there is provided a substrate processing apparatus, including: a processing chamber for performing a processing of forming a high dielectric constant film on a substrate; a processing gas supply system for supplying a processing gas into the processing chamber in order to form the high dielectric constant film; and a cleaning gas supply system for supplying a cleaning gas, which comprises a halogen-based gas other than a fluorine-based gas, into the processing chamber in order to remove materials including the high dielectric constant film deposited on an inside of the processing chamber, wherein a metal member is installed inside the processing chamber, and a DLC film is formed on at least a part of a surface of the metal member where the cleaning gas contacts.

According to another aspect of the present invention, there is provided a manufacturing method of a semiconductor device, including: loading a substrate into a processing chamber in which a metal member is installed, wherein a DLC film is formed on a surface of the metal member; performing a process of forming a high dielectric constant film on the substrate by supplying a processing gas into the processing chamber; unloading the processed substrate from the processing chamber; and removing materials including the high dielectric constant film deposited on an inside of the processing chamber by supplying a cleaning gas, which comprises a halogen-based gas other than a fluorine-based gas, into the processing chamber.

### BRIEF DESCRIPTION OF THE DRAWINGS

FIG. 1 is a graph showing the evaluation result for the erosion resistance of a DLC film.

FIG. 2 is a graph showing the evaluation result for the oxidation resistance of a DLC film.

FIG. 3 is a perspective view of a substrate processing apparatus in accordance with an embodiment of the present invention.

FIG. 4 is a side perspective view of a substrate processing apparatus in accordance with an embodiment of the present invention.

FIG. 5 is a vertical cross-sectional view of a processing furnace installed in a substrate processing apparatus in accordance with an embodiment of the present invention.

FIG. 6 is a cross-sectional view of the processing furnace taken along the line A-A of FIG. 5.

FIG. 7 is a table showing a list of various bond energies.

FIG. 8 is a graph showing the evaluation result for the composition of a DLC film.

### DETAILED DESCRIPTION OF THE PREFERRED EMBODIMENTS

As explained above, in the conventional dry etching method, a surface of a metal member installed in a processing chamber may be eroded when etching deposited materials, and the metal contamination may occur on a substrate or in the processing chamber. Therefore, the inventors conducted the study on a method for suppressing the erosion of the metal member, and found the fact that the erosion of the metal member can be suppressed by forming a diamond-like carbon (DLC) film (described later) on at least a part of a surface of the metal member installed in the processing chamber where the cleaning gas contacts. Furthermore, the suppression of erosion by the DLC film is particularly effective in the case of using a gas including a halogen-based gas such as a chlorine-based gas or a bromine-based gas, except for a fluorine-based gas, as a cleaning gas.

The halogen-based gas means a gas containing halogen elements, and the fluorine-based gas, the chlorine-based gas, and the bromine-based gas means a gas containing fluorine atoms, a gas containing chlorine atoms, and a gas containing bromine atoms, respectively.

Based upon the above fact, the inventors have invented a substrate processing apparatus including: a processing chamber for performing a processing of forming a high dielectric constant film on a substrate; a processing gas supply system for supplying a processing gas for forming the high dielectric constant film into the processing chamber; and a cleaning gas supply system for supplying a cleaning gas, which includes a halogen-based gas other than a fluorine-based gas to remove materials including the high dielectric constant film deposited on the inside of the processing chamber, into the processing chamber, wherein a metal member is installed in the processing chamber, and a DLC film is formed on at least a part of a surface of the metal member where the cleaning gas.

Furthermore, based upon the above fact, the inventors have invented a manufacturing method of a semiconductor device including loading a substrate into a processing chamber in which a metal member is installed, wherein a DLC film is formed on a surface of the metal member; performing a process of forming a high dielectric constant film on the substrate by supplying a processing gas into the processing chamber; unloading the processed substrate from the processing chamber; and removing materials including the high dielectric constant film deposited on an inside of the processing chamber by supplying a cleaning gas, which comprises a halogen-based gas other than a fluorine-based gas, into the processing chamber.

Hereinafter, explanation will be given on an etching mechanism in a processing chamber of a substrate processing apparatus in accordance with an embodiment of the present invention. In the following explanation, HfO₂ may be deposited on the inside of the processing chamber, and a cleaning gas including a chlorine-based BCl₃ gas is supplied from a cleaning gas supply system as a halogen-based gas not including a fluorine-based gas. In addition, the metal member installed in the processing chamber may be configured by a metal such as SUS including Ni, Cr, and Fe.

To etch HfO₂ which is a deposited material by a cleaning gas including a chlorine-based gas or a bromine-based gas as a halogen-based gas other than a fluorine-based gas, it is needed to perform processes such as a process of breaking an Hf—O bond, a process of forming reaction products having high steam pressure such as chlorides or bromides of Hf, and a process of desorbing the reaction products. In order to break the Hf—O bond in the desorption process, it is needed to form a new bond having bond energy (Bond Strength) higher than that of the Hf—O bond.

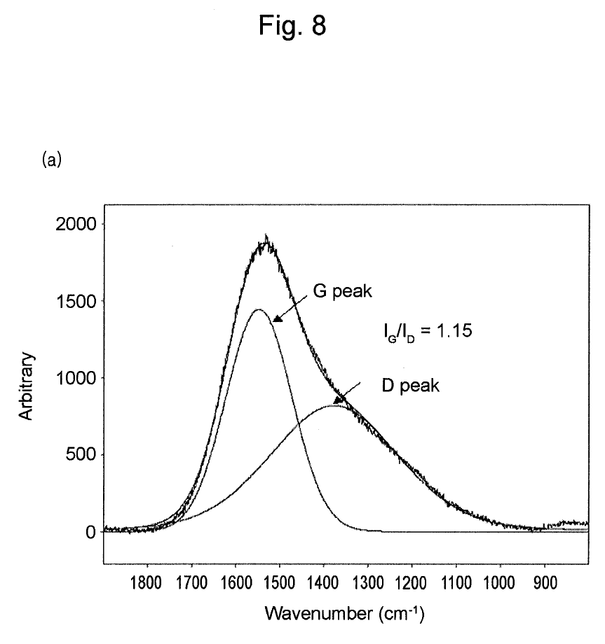

FIG. 7 shows a list of various kinds of bond energy (the source: Lide. D. R. ed. CRC Handbook of Chemistry and Physics, 79 th ed., Boca Raton, Fla., CRC Press, 1998). Referring to FIG. 7, since an Hf—O bond has high bond energy of 8.30 eV, HfO₂ is relatively difficult to remove by etching. On the other hand, in the case where a gas including, for example, BCl₃ that is a boron-containing chlorine-based gas is used as a cleaning gas, because bond energy of a B—O bond is 8.38 eV higher than the bond energy of the Hf—O bond, the Hf—O bond can be broken, and the above-mentioned process can be performed.

When a cleaning gas including BCl₃ excited by heat or plasma is supplied into the processing chamber where HfO₂ is deposited, as shown in the following formula (1), chlorine (Cl) is released from BCl₃. Also, oxygen (O) is released from an Hf—O bond of HfO₂ to form a B—O bond, and high volatile HfCl₄, BOCl, (BOCl)₃ are formed as reaction products. The etching reaction is performed by volatilization (desorption) of the reaction products.

HfO₂+2BCl₃→HfO₂+2BCl+4Cl→HfCl₄+2(BOCl) (1)

In addition, while the above-mentioned etching reaction is performed, a suppressing species BClₓ of a surface reaction (deposited species) such as BCl₂ may be formed and a BₓCl_{y} protective film may be formed on a surface of HfO₂ to suppress the etching reaction. In this case, by adding a small amount of O₂ used as an oxygen-containing gas to BCl₃ which is supplied to HfO₂, the etching reaction can be accelerated. That is, as shown in the following formula (2), the reaction between BCl₂ and O₂ results in formation of high volatile BOCl or (BOCl)₃, reduction of the density of BClₓ as a suppressing species of a surface reaction for suppressing formation of the BₓCl_{y} protective film, increase in the influence of BCl or Cl for HfO₂, and acceleration of the etching reaction.

2BCl₂+O₂→BOCl+BCl+2Cl (2)

When a cleaning gas including BCl₃ is supplied to HfO₂ deposited on the inside of the processing chamber, the cleaning gas is supplied to a surface of the metal member installed in the processing chamber. In this case, although a metal oxide film or a metal fluoride film for preventing the metal contamination is formed on the surface of the metal member, the metal oxide film or the metal fluoride film is inevitably etched by the cleaning gas.

In the case that the metal member is made of a metal including Ni, Cr, and Fe, the metal oxide film formed on the surface of the metal member is configured by a Ni—O bond, a Cr—O bond, or a Fe—O bond. However, as shown in FIG. 7, bond energies of these bonds are 3.95 eV, 4.44 eV, and 4.04 eV, respectively, and all of these are lower than 8.38 eV which is the bond energy of the B—O bond. Therefore, when a cleaning gas is supplied to the metal oxide film, oxygen (O) is released from the Ni—O bond, the Cr—O bond, and the Fe—O bond by boron (B) included in the cleaning gas. In addition, since the bond energies of the NI—O bond, the Cr—O bond, and the Fe—O bond are lower than the 8.30 eV which is the bond energy of the Hf—O bond, oxygen (O) is released from the Ni—O bond, the Cr—O bond, and the Fe—O bond before oxygen (O) is released from the Hf—O bond. That is, the metal oxide film configured by the Ni—O bond, the Cr—O bond, and the Fe—O bond is less resistant against etching than HfO₂ with respect to a cleaning gas including BCl₃.

Also, the metal fluoride film formed on the surface of the metal member is configured by an Ni—F bond or a Cr—F bond. However, as shown in FIG. 7, bond energies of these bonds are 4.45 eV, and 4.61 eV, respectively, and both of these are lower than 7.84 eV which is the bond energy of the B—F bond. Therefore, when a cleaning gas is supplied to the metal fluoride film, fluorine (F) is released from the Ni—F bond and the Cr—F bond by boron (B) included in the cleaning gas. That is, the metal fluoride film configured by the Ni—F bond and the Cr—F bond is less resistant against etching with respect to a cleaning gas including BCl₃.

For this reason, in the substrate processing apparatus in accordance with the current embodiment, a DLC film is formed on at least a part of a surface of the metal member in the processing chamber where the cleaning gas contacts.

The DLC film is formed of an amorphous carbon film. The carbon bonding state of the DLC film is configured by both a diamond structure (sp³) and a graphite structure (sp²). As the diamond component (sp³ bonding component) of the DLC film is increased, the resistance of the DLC film is improved. On the other hand, as the graphite component (sp² bonding component) of the DLC film is increased, the resistance of the DLC film is reduced. That is, as the strong diamond bonding is increased, the etching becomes difficult, and on the other hand, as the graphite component is increased, the etching rate becomes higher.

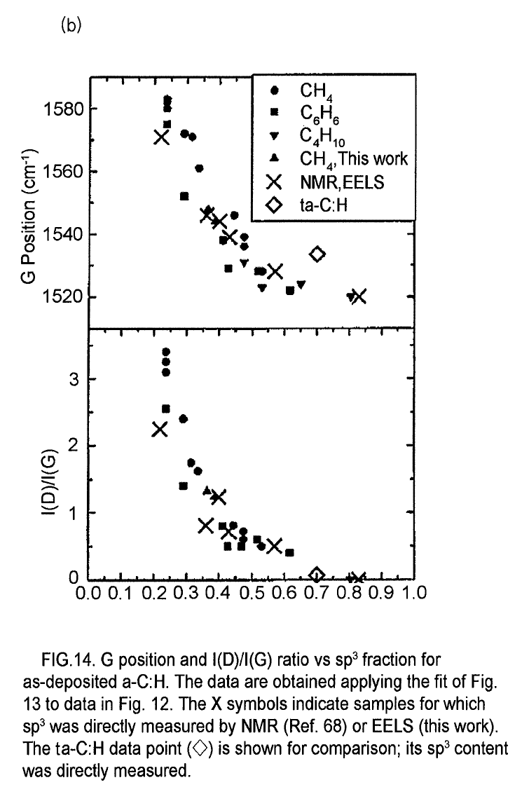

Raman spectroscopy is an effective analysis method for identification of these structures or evaluation of crystallinity. Diamond is configured by covalent crystals with sp hybrid orbital, and a lattice vibration band of diamond is observed near 1350 cm⁻¹, while graphite is configured by stacking six-membered circular net-shaped planar carbon layers of sp² hybrid orbital, and a lattice vibration band of graphite is observed near 1580 cm⁻¹. DLC is amorphous carbon including a lot of sp³ structures, and sp³ property can be observed by calculating I_{G}/I_{D} which is a dimension ratio of D band and G band. As the peak strength of the D band becomes higher, the sp³ property increases. The DLC film used for this evaluation was analyzed by Raman spectroscopy, and I_{G}/I_{D} was 1.15 (refer to FIG. 8(a)). A composition ratio (rate) of sp³ with respect to sp² and sp³, that is, sp³/(sp²+sp³) is obtained as 0.45 from this peak strength ratio. Considering the erosion evaluation result by the electrochemical experiment (described later) and composition of the DLC film, it is preferable that sp³/(sp²+sp³) is 0.4 or more. Also, a method of obtaining sp³ from I_{G}/I_{D} in Raman spectroscopy for the DLC film refers to the following document (see FIG. 8(b)).

“A. C. Ferrari, J. Robertson: Physical Review B, Vol. 61 (2000) 14095”

In the DLC film, unlike the etching of the HfO₂ or the metal oxide film, release of oxygen (O) caused by boron (B) does not occur. The etching of the DLC film caused by BCl₃ occurs by attack of activated chlorine (Cl) desorbed from BCl₃ to C—C bond, and as shown in FIG. 7, bond energy of the C—C bond is 6.29 eV while bond energy of a C—Cl bond is 4.11 eV. Therefore, the DLC film is a material which is very difficult to react with BCl₃, and thus it is difficult to etch the DLC film by BCl₃. That is, by forming the DLC film on at least a part of a surface of the metal member in the processing chamber where the cleaning gas contacts, the erosion of the metal member in the process chamber can be suppressed and the metal contamination can be reduced.

In the above explanation, BCl₃ of a chlorine-based gas is instanced, and now, a halogen-based gas such as F₂ of a fluorine-based gas or BBr₃ of a bromine-based gas will be considered. As shown in FIG. 7, bond energy of a C—F bond is 5.7 eV, and bond energy of a C—Br bond is 2.9 eV. The bond energy of the C—F bond is similar to the bond energy of the C—C bond, and the degree of attack of the etching by F₂ is high with respect to the C—C bond, compared to BCl₃ or BBr₃. That is, the possibility that the DLC film is etched by F₂ is much higher than the possibility that the DLC film is etched by BCl₃ or BBr₃. On the other hand, since the bond energy of the C—Br bond is quite lower than the bond energy of the C—C bond, the possibility that the DLC film is etched by BBr₃ is very low. Accordingly, the DLC film is not suitable for preventing the metal contamination with respect to a fluorine-based etching gas such as F₂ in an aspect of the etching resistance, but is suitable for preventing the metal contamination with respect to a chlorine-based etching gas and a bromine-based etching gas such as BCl₃ or BBr₃ of a halogen-based etching gas. Therefore, in the present invention, a chlorine-based gas and a bromine-based gas, that is, a halogen-based gas other than a fluorine-based gas will be used as a cleaning gas (etching gas).

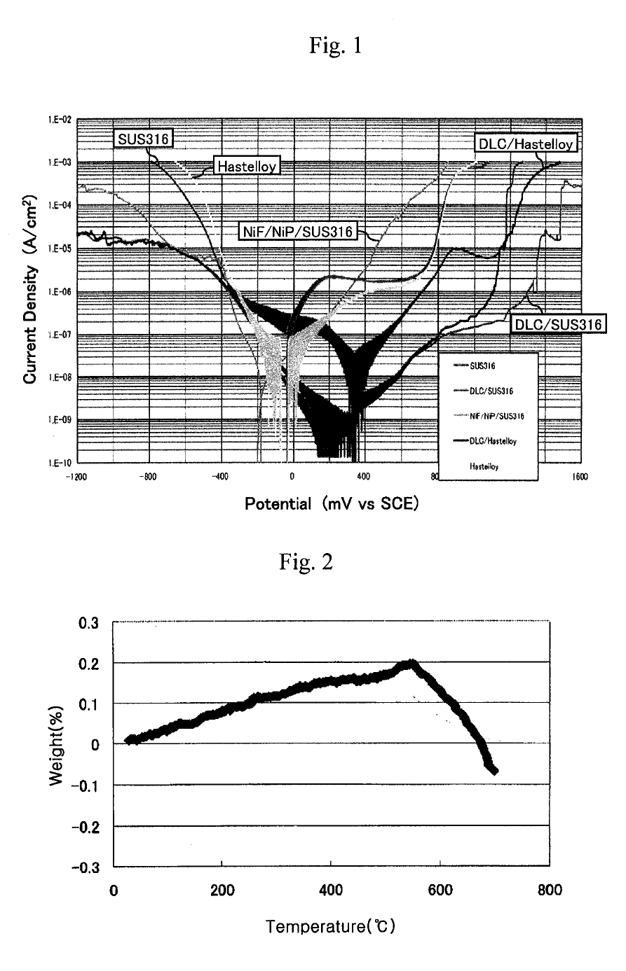

FIG. 1 shows the result of an electrochemical experiment (polarization curve measurement experiment) for evaluating the erosion resistance of the DLC film. In the electrochemical experiment, a metal sample piece and a Pt piece were provided as electrodes so as to face each other in a hydrochloric acid (HCl) aqueous solution of about PH 2, a potential were applied between these electrodes, and then a polarization curve was measured. Five kinds of the metal sample piece were prepared, such as non-coated SUS316 (SUS316), non-coated Hastelloy (Hastelloy, registered trademark), SUS316 coated with a DLC film (DLC/SUS316), Hastelloy coated with a DLC film (DLC/Hastelloy), and SUS316 sequentially coated with a NiP film and a NiF film (NiF/NiP/SUS316), and each sample was masked with dielectric paints except for a measured surface (7×7 mm). An sp³ ratio (sp³/(sp²+sp³)) of the DLC film was set to 0.4˜0.5, and the thickness of the DLC film was set to 0.8˜3 μm. In FIG. 1, a horizontal axis represents a potential applied between the platinum (Pt) electrode and the metal sample piece electrode, and a vertical axis represents the current density. As shown in FIG. 1, the erosion current densities of the metal sample pieces were 2.5×10⁻⁸, 5.0×10⁻⁸, 1.0×10⁻⁹, 1.0×10⁻⁹, 8.0×10⁻⁹ A/cm², respectively. That is, the samples coated with the DLC film (DLC/SUS316, DLC/Hastelloy) have the erosion current density corresponding to 1/25 of the erosion current density of the non-coated SUS316, and corresponding to ⅛ of the erosion current density of the SUS316 sequentially coated with a NiP film and a NiF film (NiF/NiP/SUS316). The erosion rates of the metal sample pieces were 0.26, 0.49, 0.01, 0.01, 0.08 nm/year, respectively. That is, it can be found that the DLC film has the highest erosion resistance against a cleaning gas.

Also, the inventors evaluated the etching of the above-mentioned metal sample pieces by using BCl₃ and O₂. In detail, the same sample pieces as the above-mentioned metal sample pieces were prepared, and the sample pieces were provided in a processing chamber of an apparatus for evaluation, and BCl₃ and O₂ were supplied into the processing chamber to perform thermal etching. Also, the thermal etching condition was set in a manner such that a high dielectric constant film such as a HfO₂ film can be etched, specifically, in the range as follows, an etching temperature of 300˜550° C., an etching pressure of 13.3˜66500 Pa, a BCl₃ flow rate of 0.1˜10 slm, and an O₂ flow rate of 0.1˜10 slm.

As for the etching evaluation result, erosion was found in the non-coated SUS316 (SUS316) or the SUS316 sequentially coated with a NiP film and a NiF film (NiF/NiP/SUS316), while erosion was not found in the sample pieces coated with the DLC film. By this evaluation, it can be seen that the DLC film, particularly the DLC film with sp³/(sp²+sp³) of 0.4 or more has the highest resistance against an etching gas including a halogen-based gas such as BCl₃ and O₂ other than a fluorine-based gas, and has the highest erosion resistance. In addition, it can be seen that the thickness of the DLC film may be at least 0.8 μm or more. If the DLC film is too thin, the erosion of the metal member caused by an etching gas and the metal contamination cannot be sufficiently suppressed. On the other hand, if the DLC film is too thick, for example, the thickness of the DLC film is more than 5 μm, cracks may be generated in the DLC film or the DLC film may be peeled off because of stress (heat, film). Accordingly, it is preferable that the thickness of the DLC film ranges from 0.8 μm to 5 μm.

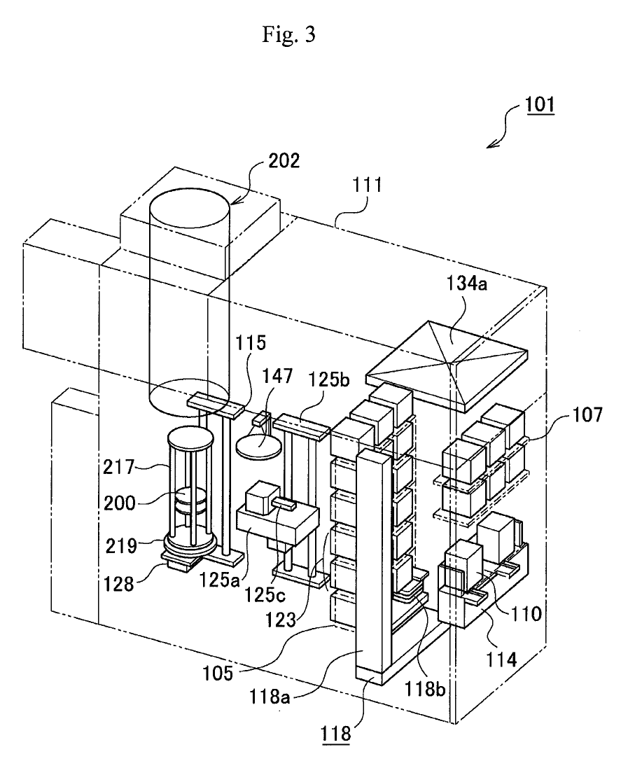

Also, the inventors conducted studies on the anti-oxidation of the DLC film. In detail, with a thermogravimetry/Differential Thermal Analysis (TG-DTA) apparatus, a sample configured by a Si wafer with a DLC film formed on a surface is shattered, and its weight change is measured while heating the sample in an atmosphere. The DLC film is set to sp³/(sp²+sp³) of 0.4˜0.45 and the thickness of 0.83 μm. FIG. 2 shows the evaluation result for the oxidation resistance of the DLC film. In FIG. 2, a horizontal axis represents a temperature of the sample, and a vertical axis represents a weight of the sample. As shown in FIG. 2, the weight of the sample gradually increases until the temperature reaches 550° C., and thereafter the weight of the sample decreases. It is considered that the weight increase of the sample is caused by that Si reacts with oxygen (O) of atmosphere to form SiO₂, and the weight decrease of the sample is caused by that carbon (C) reacts with oxygen (O) of atmosphere to become CO and then is volatilized. That is, it can be seen that the heat resistant temperature of the DLC film is 550° C. or less in an oxygen-containing atmosphere. From the above results, the inventors found the fact that it is preferable to maintain a surface temperature of the metal member having the DLC film at 550° C. or less.

### Embodiment

Hereinafter, an embodiment of the present invention will be explained with reference to the attached drawings.

### (1) A Structure of a Substrate Processing Apparatus

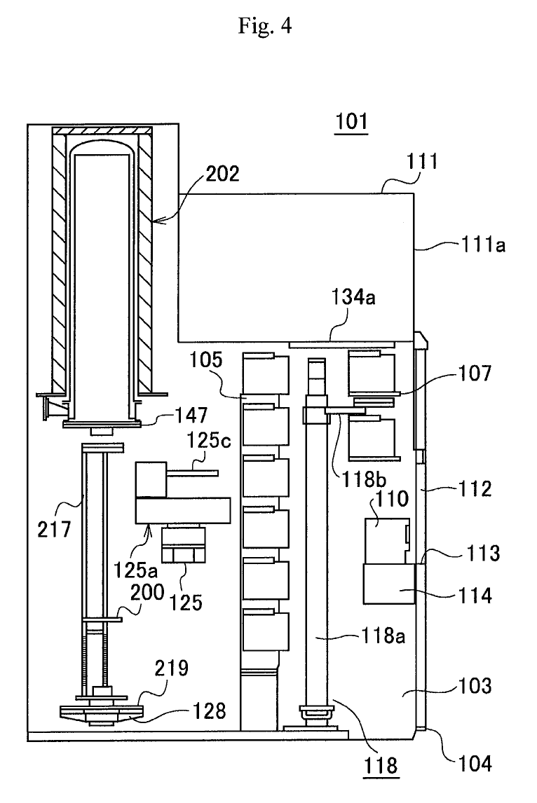

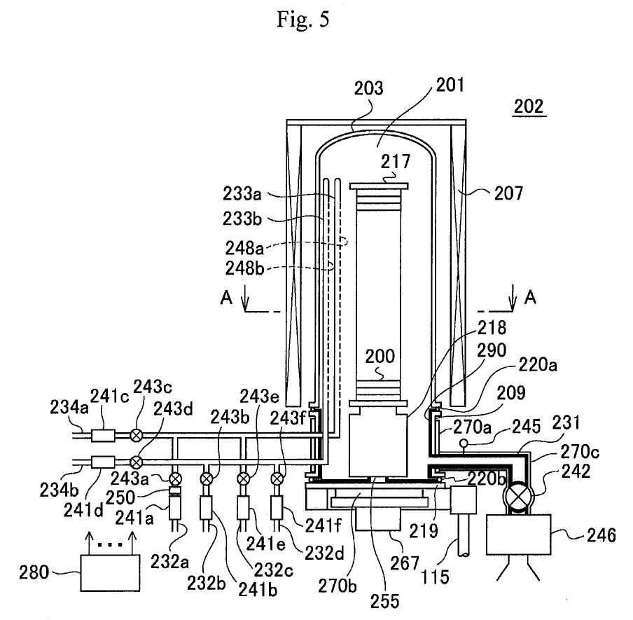

First, with reference to FIG. 3 and FIG. 4, an explanation will be given on an exemplary structure of a substrate processing apparatus 101 configured to perform a substrate processing process in a manufacturing process of a semiconductor device. FIG. 3 is a perspective view of the substrate processing apparatus 101 in accordance with an embodiment of the present invention, and FIG. 4 is a side perspective view of the substrate processing apparatus 101 in accordance with an embodiment of the present invention.

As shown in FIG. 3 and FIG. 4, the substrate processing apparatus 101 in accordance with the current embodiment is provided with a housing 111. At the lower part of a front wall 111a of the housing 111, a front maintenance gate 103 is provided as an opening part for maintenance of the inside of the housing 111. At the front maintenance gate 103, a front maintenance door 104 is installed, which opens and closes the front maintenance gate 103. To load/unload a wafer (substrate) 200 made of a material such as silicon into/from the housing 111, a cassette 110 is used as a wafer carrier (substrate container) receiving a plurality of wafers 200. At the front maintenance door 104, a cassette carrying in/out opening (substrate container carrying in/out opening) 112, which is an opening for loading/unloading the cassette 110 into/from the housing 111, is installed in communication with the inside and outside of the housing 111. The cassette carrying in/out opening 112 is designed to be opened and closed by a front shutter (mechanism for opening and closing the substrate container carrying in/out opening) 113. At the inside of the housing 111 of the cassette carrying in/out opening 112, a cassette stage (substrate container transfer table) 114 is installed. The cassette 110 is designed to be carried onto the cassette stage 114, and also, carried from the cassette stage 114 to the outside of the housing 111, by an in-plant carrying unit (not shown).

The cassette 110 is put on the cassette stage 114 by the in-plant carrying unit in a manner such that the wafer 200 maintains a vertical position inside the cassette 110 and a wafer carrying in/out opening of the cassette 110 faces upward. The cassette stage 114 is configured such that the cassette 110 is rotated 90 degrees in a longitudinal direction to the backside of the housing 111, and the wafer 200 inside the cassette 110 takes a horizontal position, and the wafer carrying in/out opening of the cassette 110 faces the backside of the housing 111.

At nearly the center part inside the housing 111 in a forward and backward direction, a cassette shelf (substrate container placement shelf) 105 is installed. The cassette shelf 105 is configured to store a plurality of cassettes 110 in a plurality of stages and a plurality of rows. At the cassette shelf 105, a transfer shelf 123 is disposed to accommodate the cassettes 110 which are targets to be carried by a wafer transfer mechanism (described later) 125. In addition, at the upside of the cassette stage 114, a standby cassette shelf 107 is disposed to accommodate a standby cassette 110.

Between the cassette stage 114 and the cassette shelf 105, a cassette carrying unit (substrate container carrying unit) 118 is installed. The cassette carrying unit 118 is provided with a cassette elevator (substrate container elevating mechanism) 118a, which is capable of holding and moving the cassette 110 in a vertical direction, and a cassette carrying mechanism (substrate container carrying mechanism) 118b, which is capable of holding and moving the cassette 110 in a horizontal direction. The cassette carrying unit 118 is designed to carry the cassette 110 onto and out of the cassette stage 114, the cassette shelf 105, the standby cassette shelf 107, and/or the transfer shelf 123, by the continuous operations of the cassette elevator 118a and the cassette carrying mechanism 118b.

At the backside of the cassette shelf 105, the wafer transfer mechanism (substrate transfer mechanism) 125 is installed. The wafer transfer mechanism 125 is provided with a wafer transfer unit (substrate transfer unit) 125a, which is capable of horizontally rotating or straightly moving the wafer 200, and a wafer transfer unit elevator (substrate transfer unit elevating mechanism) 125b for moving the wafer transfer unit 125a in a vertical direction. In addition, the wafer transfer unit 125a is provided with tweezers (substrate holding body) 125c which maintain the wafer 200 at a horizontal position. By the continuous operations of the wafer transfer unit elevator 125b and the wafer transfer unit 125a, the wafer 200 may be picked up from the inside of the cassette 110 disposed on the transfer shelf 123 and charged into a boat (substrate holding tool, described later) 217, or may be discharged from the boat 217 and placed into the cassette 110 disposed on the transfer shelf 123.

At the rear upper part of the housing 111, a processing furnace 202 is installed. An opening is formed at the lower end part of the processing furnace 202, and the opening is configured to be opened and closed by a furnace throat shutter (furnace throat opening/closing mechanism) 147. Also, the configuration of the processing furnace 202 will be explained later.

At the downside of the processing furnace 202, a boat elevator (substrate holding tool elevating mechanism) 115 is installed as an elevating mechanism to elevate and carry the boat 217 in/out of the processing furnace 202. At an elevating table of the boat elevator 115, an arm 128 is installed as a connecting tool. On the arm 128, a seal cap 219 is installed in a horizontal position, as a cover which vertically supports the boat 217, and air-tightly closes the lower end part of the processing furnace 202 when the boat 217 moves upward by the boat elevator 115.

The boat 217 is provided with a plurality of holding members, and is configured to hold a plurality of sheets (for example, from about 50 to 150 sheets) of wafers 200 each horizontally in multiple stages, in a state that the centers thereof are aligned and put in a vertical direction.

At the upside of the cassette shelf 105, a clean unit 134a is installed with a supply fan and a dust filter. The clean unit 134a is configured to make a flow of clean air, that is, purified atmosphere through the inside of the housing 111

Also, a clean unit (not shown) configured by a supply fan and a dust filter for supplying clean air is installed in the left end part of the housing 111, which is the opposite side to the wafer transfer unit elevator 125b and the boat elevator 115. The clean air blown from the clean unit (not shown) flows through the wafer transfer unit 125a and the boat 217, and then flows in an exhaust unit (not shown) and is exhausted out of the housing 111.

### (2) An Operation of the Substrate Processing Apparatus

Then, explanation will be given on the operation of the substrate processing apparatus 101 in accordance with an embodiment of the present invention.

First, before the cassette 110 is placed onto the cassette stage 114, the cassette carrying in/out opening 112 is opened by the front shutter 113. Thereafter, the cassette 110 is carried onto the cassette stage 114 from the cassette carrying in/out opening 112 by the in-plant carrying unit. At this time, the cassette 110 is placed on the cassette stage 114 in a manner such that the wafer 200 is held in a vertical position, and the wafer carrying in/out opening of the cassette 110 faces upward. After that, the cassette 110 is rotated 90 degrees in a longitudinal direction toward the backside of the housing 111 by the cassette stage 114. As a result, the wafer 200 inside the cassette 110 takes a horizontal position, and the wafer carrying in/out opening of the cassette 110 faces the backside of the housing 111.

Then, the cassette 110 is automatically carried and delivered to a specified shelf position of the cassette shelf 105 or the standby cassette shelf 107 by the cassette carrying unit 118, and stored temporarily and transferred to the transfer shelf 123 from the cassette shelf 105 or the standby cassette shelf 107, or directly transferred to the transfer shelf 123.

After the cassette 110 is transferred to the transfer shelf 123, the wafer 200 is picked up from the cassette 110 through the wafer carrying in/out opening by the tweezers 125c of the wafer transfer unit 125a, and is charged into the boat 217 disposed at the backside of a transfer chamber 124 by the continuous operations of the wafer transfer unit 125a and the wafer transfer unit elevator 125b. After delivering the wafer 200 to the boat 217, the wafer transfer mechanism 125 returns to the cassette 110 and charges the next wafer 200 into the boat 217.

When predetermined sheets of the wafers 200 are charged into the boat 217, the lower end part of the processing furnace 202 is opened by the furnace throat shutter 147. Subsequently, the boat 217 holding a group of wafers 200 is loaded into the processing furnace 202 by elevating the seal cap 219 using the boat elevator 115. After the loading, a predetermined process is performed on the wafer 200 in the processing furnace 202. Such a process will be explained later. After the predetermined process, the wafer 200 and the cassette 110 are carried out of the housing 111 in the reverse order.

### (3) A Structure of the Processing Furnace

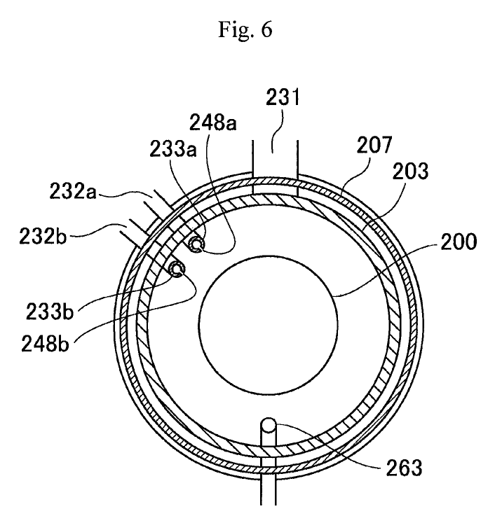

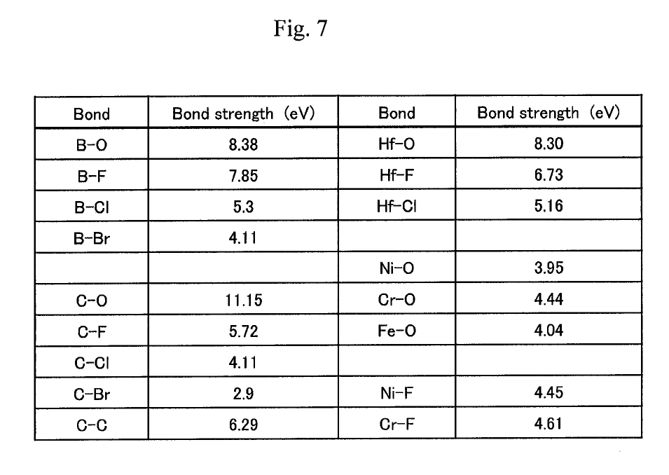

Next, with reference to FIG. 5 and FIG. 6, explanation will be given on the structure of the processing furnace 202 installed in the substrate processing apparatus 101. FIG. 5 is a vertical cross-sectional view of the processing furnace 202 installed in the substrate processing apparatus 101 in accordance with the current embodiment. FIG. 6 is a cross-sectional view of the processing furnace 202 taken along the line A-A of FIG. 5.

As shown in FIG. 5, the processing furnace 202 includes a heater 207 as a heating means (heating unit). The heater 207 has a cylindrical shape and is supported by a heater base (not shown) used as a supporting plate so as to be vertically fixed.

At the inside of the heater 207, a process tube 203 used as a reaction tube is installed concentrically with the heater 207. The process tube 203 is made of a heat-resistant material such as quartz (SiO₂) or silicon carbide (SiC), and has a cylindrical shape with a closed upper end and an opened lower end. In a hollow part of the process tube 203, a processing chamber 201 is installed, which performs a process for forming a high dielectric constant film on the wafer 200 as a substrate. The processing chamber 201 is configured to hold wafers 200 each horizontally in multiple stages, in a state that they are aligned and put in a vertical direction by the boat 217.

At the downside of the process tube 203, a manifold (furnace throat flange part) 209 is installed coaxially with the process tube 203. The manifold 209 is made of a material such as stainless steel, and has a cylindrical shape with opened upper and lower ends. The manifold 209 is engaged with the process tube 203, and is configured to support the process tube 203. In addition, between the manifold 209 and the process tube 203, an O-ring 220a is disposed as a seal. Since the manifold 209 is supported by the heater base, the process tube 203 is fixed in a vertical direction. The process tube 203 and the manifold 209 constitute a reaction vessel.

A film-forming gas supply system, which supplies a film-forming gas to the inside of the processing chamber 201 as a high dielectric constant material for forming a high dielectric constant film, and a cleaning gas supply system, which supplies a cleaning gas to the inside of the processing chamber 201 for removing materials including a high dielectric constant film deposited on the inside of the processing chamber 201, are connected to the manifold 209. The film-forming gas supply system is configured to supply a film-forming source and an oxidizing agent, as a film-forming gas, into the processing chamber 201. Also, the cleaning gas supply system is configured to supply an additive gas and a halogen-based gas which is an etching gas, as a cleaning gas, into the processing chamber 201.

Specifically, a first nozzle 233a which is a first gas introduction part and a second nozzle 233b which is a second gas introduction part are connected to the processing chamber 201 so as to respectively communicate with the inside of the processing chamber 201. A first gas supply pipeline 232a and a second gas supply pipeline 232b are connected to the first nozzle 233a and the second nozzle 233b, respectively. In addition, a third gas supply pipeline 232c and a fourth gas supply pipeline 232d are connected to the first gas supply pipeline 232a and the second gas supply pipeline 232b, respectively. As such, the four gas supply pipelines 232a, 232b, 232c and 232d, and the two nozzles 233a and 233b are installed, as a gas supply route for supplying a plural kinds, herein, four kinds of gases to the processing chamber 201. The first gas supply pipeline 232a and the second gas supply pipeline 232b constitute the film-forming gas supply system, and the third gas supply pipeline 232c and the fourth gas supply pipeline 232d constitute the cleaning gas supply system.

At the first gas supply pipeline 232a, a first mass flow controller 241a which is a flow rate controller (flow rate control means), an evaporator 250, and a first valve 243a which is an opening-closing valve are installed in this order from the upstream side. The first mass flow controller 241a is configured as a liquid mass flow controller for controlling a flow rate of a liquid material which is in liquid state at room temperature and used as a film-forming material. Also, a first inert gas supply pipeline 234a for supplying an inert gas is connected to the downstream side of the first valve 243a of the first gas supply pipeline 232a. At the first inert gas supply pipeline 234a, a third mass flow controller 241c which is a flow rate controller (flow rate control means) and a third valve 243c which is an opening-closing valve are installed in this order from the upstream side. The first nozzle 233a is connected to a leading end part (downstream end part) of the first gas supply pipeline 232a. The first nozzle 233a is disposed in an arc-shaped space between wafers 200 and the inner wall of the process tube 203 forming the processing chamber 201, from the lower part to the upper part of the inner wall of the process tube 203, in the stacked direction of the wafers 200. At the side surface of the first nozzle 233a, a plurality of first gas supply holes 248a are formed, which are supply holes for supplying gases. The first gas supply holes 248a have the same size and are arranged at the same pitch from the lower side to the upper side.

At the second gas supply pipeline 232b, a second mass flow controller 241b which is a flow rate controller (flow rate control means) and a second valve 243b which is an opening-closing valve are installed in this order from the upstream side. A second inert gas supply pipeline 234b for supplying an inert gas is connected to the downstream side of the second valve 243b of the second gas supply pipeline 232b. At the second inert gas supply pipeline 234b, a fourth mass flow controller 241d which is a flow rate controller (flow rate control means) and a fourth valve 243d which is an opening-closing valve are installed in this order from the upstream side. The second nozzle 233b is connected to a leading end part (downstream end part) of the second gas supply pipeline 232b. The second nozzle 233b is disposed in the arc-shaped space between the wafers 200 and the inner wall of the process tube 203 forming the processing chamber 201, from the lower part to the upper part of the inner wall of the process tube 203, in the stacked direction of the wafers 200. At the side surface of the second nozzle 233b, a plurality of second gas supply holes 248b are formed, which are supply holes for supplying gases. The second gas supply holes 248b have the same size and are arranged at the same pitch from the lower side to the upper side.

The third gas supply pipeline 232c is connected to the downstream side of the connecting portion between the first gas supply pipeline 232a and the first inert gas supply pipeline 234a. At the third gas supply pipeline 232c, a fifth mass flow controller 241e which is a flow rate controller (flow rate control means) and a fifth valve 243e which is an opening-closing valve are installed in this order from the upstream side.

The fourth gas supply pipeline 232d is connected to the downstream side of the connecting portion between the second gas supply pipeline 232b and the second inert gas supply pipeline 234b. At the fourth gas supply pipeline 232d, a sixth mass flow controller 241f which is a flow rate controller (flow rate control means) and a sixth valve 243f which is an opening-closing valve are installed in this order from the upstream direction.

As a film-forming source for forming a high dielectric constant film made of a high dielectric constant material, for example, a hafnium source gas prepared by evaporating TetrakisEthylMethylAminoHafnium (TEMAH, Hf[(C₂H₅)(CH₃)N]₄) which is a hafnium organic material, is supplied from the first gas supply pipeline 232a to the inside of the processing chamber 201 through the first mass flow controller 241a, the evaporator 250, the first valve 243a, and the first nozzle 233a.

Also, from the second gas supply pipeline 232b, for example, an ozone gas (O₃) used as an oxidizing agent is supplied into the processing chamber 201 through the second mass flow controller 241b, the second valve 243b, and the second nozzle 233b.

Also, from the third gas supply pipeline 232c, for example, boron trichloride (BCl₃) which is a halogen-based gas used as a cleaning gas (etching gas) is supplied to the inside of the processing chamber 201 through the fifth mass flow controller 241e, the fifth valve 243e, the first gas supply pipeline 232a, and the first nozzle 233a.

Also, from the fourth gas supply pipeline 232d, for example, an oxygen gas (O₂) used as a cleaning gas (etching gas) and an additive to a halogen-based gas is supplied to the inside of the processing chamber 201 through the sixth mass flow controller 241f, the sixth valve 243f, the second gas supply pipeline 232b, and the second nozzle 233b.

In addition, at the same time when the above gases are supplied to the inside of the processing chamber 201, an inert gas may be supplied from the first inert gas supply pipeline 234a to the first gas supply pipeline 232a through the third mass flow controller 241c and the third valve 243c, and also an inert gas may be supplied from the second inert gas supply pipeline 234b to the second gas supply pipeline 232b through the fourth mass flow controller 241d and the fourth valve 243d. By supplying the inert gas, the above gases may be diluted or pipelines which were not in use may be purged.

At the manifold 209, an exhaust pipeline 231 is installed, which exhausts an atmosphere inside the processing chamber 202. A vacuum pump 246 used as a vacuum exhaust unit is connected to the downstream side of the exhaust pipeline 231, that is, an opposite side to the manifold 209 through a pressure sensor 245 used as a pressure detector and an auto pressure controller (APC) valve 242 used as a pressure controller. Therefore, the exhaust pipeline 231 is configured to evacuate the processing chamber 201 so that the inside of the processing chamber 201 reaches a predetermined pressure (vacuum degree). The APC valve 242 is an opening-closing valve configured to be opened or closed to evacuate the processing chamber 201 or stop the evacuation of the processing chamber 201, and configured to be adjusted in its opening size to control the pressure inside the processing chamber 201.

As explained above, at the downside of the manifold 209, a seal cap 219 is installed as a furnace throat cover capable of air-tightly closing a lower end opening of the manifold 209. The seal cap 219 is disposed at the lower side of the manifold 209 and configured to make contact with the manifold 209 from the lower side of the manifold 209 in a vertical direction. The seal cap 209 is made of a metal such as stainless steel, and has a disk shape. On an upper surface of the seal cap 219, an O-ring 220b is installed as a seal which contacts the lower end of the manifold 209. At the side of the seal cap 219 opposite to the processing chamber 201, a rotating mechanism 267 for rotating the boat 217 is installed. A rotation shaft 255 of the rotating mechanism 267 is connected to the boat 217 through the seal cap 219. By operating (rotating) the rotating mechanism 267, the boat 217 and the wafer 200 are rotated. The seal cap 219 is configured to move upward and downward by the boat elevator 115, which is vertically installed at the outside of the process tube 203 as an elevating mechanism. By moving the boat elevator 115 upward and downward, it is possible to load/unload the boat 217 into/from the processing chamber 201.

The boat 217 used as a substrate holding tool is made of a heat-resistant material such as quartz or silicon carbide, and as explained above, is configured to hold a plurality of sheets of wafers 200 horizontally in multiple stages, in a state that the centers of the wafers 200 are aligned. At the lower side of the boat 217, an insulating member 218 is installed, which is made of a heat-resistant material such as quartz or silicon carbide, and is configured so that it is difficult to transfer heat from the heater 207 to the seal cap 219. Also, the insulating member 218 may be configured by a plurality of sheets of insulating plates made of a heat-resistant material such as quartz or silicon carbide, and an insulating plate holder used to support the insulating plates horizontally in multiple stages.

As shown in FIG. 6, at the inside of the process tube 203, a temperature sensor 263 is installed as a temperature detector. By controlling power to the heater 207 based on temperature information detected by the temperature sensor 263, the inside of the processing chamber 201 can be allowed to have a desired temperature distribution.

In addition, in the current embodiment, metal members such as the manifold 209, the seal cap 219, the rotation shaft 255, the exhaust pipeline 231, or the APC valve 242 are installed in the processing furnace 202 or in the gas flow route, and a DLC (diamond-like carbon) film 290 is formed on at least a part of a surface of the metal member where the cleaning gas contacts. Specifically, an inner surface of the manifold 209, a surface of the seal cap 219, a surface of the rotation shaft 255, and inner surfaces of the exhaust pipeline 231 and the APC valve 242 are coated with the DLC film 290, which has the erosion resistance against a halogen-based gas such as BCl₃. Also, according to the current embodiment, the DLC film is used, which has sp³/(sp²+sp³) of 0.4 or more and a thickness of 0.8 μm or more.

In addition, at the manifold 209, the seal cap 219, and the exhaust pipeline 231, temperature control units 270a, 270b and 270c are installed, respectively. The temperature control unit 270a adjusts a temperature of the manifold 209, the temperature control unit 270b adjusts a temperature of the seal cap 219 and the rotation shaft 255, and the temperature control unit 270c adjusts a temperature of the exhaust pipeline 231 and the APC valve 242. The temperature control units 270a, 270b and 270c are configured by, for example, a sub-heater or a coolant circulating device (chiller).

Also, the processing furnace 202 in accordance with the current embodiment is provided with a controller 280 as a control unit (control means). The controller 280 is connected to the first to sixth mass flow controllers 241a, 241b, 241c, 241d, 241e and 241f, the first to sixth valves 243a, 243b, 243c, 243d, 243e and 243f, the evaporator 250, the APC valve 242, the heater 207, the temperature control units 270a, 270b and 270c, the vacuum pump 246, the rotating mechanism 267, the boat elevator 115, or the like. The controller 280 is configured to control the flow rate adjustment operations of the first to sixth mass flow controllers 241a, 241b, 241c, 241d, 241e and 241f, the opening and closing operations of the first to sixth valves 243a, 243b, 243c, 243d, 243e and 243f, the evaporating operation of the evaporator 250, the opening and closing operation and the pressure adjustment of the APC valve 242, the temperature adjustment operation of the heater 207, the temperature adjustment operation of the metal members by the temperature control units 270a, 270b and 270c, driving•stopping operations of the vacuum pump 246, the rotation speed of the rotating mechanism 267, the elevating operation of the boat elevator 115, or the like.

### (4) A Method of Forming a High Dielectric Constant Film, and a Cleaning Method

Next, explanation will be given on a semiconductor device manufacturing process using the processing furnace 202 of the above substrate processing apparatus 101, such as a method of forming a high dielectric constant film on the wafer 200 in the processing chamber 201 by using a high dielectric constant material and a method of cleaning the inside of the processing chamber 201. As a film-forming method, explanation will be given on an example of forming a hafnium oxide film (HfO₂, hafnia) as a high dielectric constant film on the wafer 200, by using TEMAH which is a hafnium organic material as a film-forming source and using an ozone gas (O₃) as an oxidizing agent according to an atomic layer deposition (ALD) method. Also, as a cleaning method, explanation will be given on an example of cleaning the inside of the processing chamber 201 by a thermochemical reaction using a BCl₃ gas and an O₂ gas as a cleaning gas. In the following explanation, operations of parts constituting the substrate processing apparatus 101 are controlled by the controller 280.

First, explanation will be given on a method of forming a high dielectric constant film on the wafer 200 in the processing chamber 201 by using a high dielectric constant material.

The ALD method is a technique of alternately supplying reactive gases, which become at least two kinds of raw materials for film formation, to a substrate under predetermined film-forming conditions (temperature, time, and the like), so as to allow the substrate to adsorb the reactive gases on an atomic layer basis for forming a film by a surface reaction. In this case, the formation of the film is controlled by varying the number of reactive gas supplying cycles. For example, assuming that a film-forming speed is 1 Å/cycle, 20 cycles are executed in the case of forming a 20-Å film. Hereinafter, this will be specifically explained.

First, as explained above, a substrate such as a wafer 200 is loaded into the processing chamber 201 provided with the metal member having the DLC film 290 formed on its surface. Specifically, when a plurality of sheets of wafers 200 are charged into the boat 217, as shown in FIG. 5, the boat 217 holding the wafers 200 is moved upward by the boat elevator 115 and is loaded into the processing chamber 201. In this state, the seal cap 219 seals a lower end of the manifold 209 using the O-ring 220b.

The inside of the processing chamber 201 is evacuated by the vacuum pump 246 to a desired pressure (vacuum degree). Here, the pressure in the processing chamber 201 is measured by the pressure sensor 245, and the APC valve 242 is feedback-controlled based on the measured pressure. Also, the inside of the processing chamber 201 is heated by the heater 207 to a desired temperature. Here, power to the heater 207 is feedback-controlled based on temperature information detected by the temperature sensor 263, so that the inside of the processing chamber 201 can have a desired temperature distribution. Then, as the boat 217 is rotated by the rotating mechanism 267, the wafer 200 is rotated.

Thereafter, a processing gas is supplied to the inside of the processing chamber 201 to form a high dielectric constant film on the wafer 200. Specifically, the following four steps are sequentially executed. Also, the boat 217, that is, the wafer 200, may not be rotated.

(Step 1)

The first valve 243a of the first gas supply pipeline 232a and the third valve 243c of the first inert gas supply pipeline 234a are opened, TEMAH used as a film-forming source is flown to the first gas supply pipeline 232a, and an inert gas (N₂) used as a carrier gas is flown to the first inert gas supply pipeline 234a. The inert gas is flown from the first inert gas supply pipeline 234a, and a flow rate of the inert gas is adjusted by the third mass flow controller 241c. TEMAH is flown from the first gas supply pipeline 232a, and a flow rate of TEMAH is adjusted in a liquid state by the first mass flow controller 241a which is a liquid mass flow controller. TEMAH is evaporated in the evaporator 250, mixed with the inert gas, of which the flow rate is adjusted, and then exhausted through the exhaust pipeline 231 while being supplied into the processing chamber 201 through the first gas supply holes 248a of the first nozzle 233a. In this case, by properly controlling the APC valve 242, the pressure inside the processing chamber 201 is maintained at 13.3˜1330 Pa, for example, 300 Pa. A supply amount of TEMAH controlled by the first mass flow controller 241a which is a liquid mass flow controller is set to a range of 0.01˜0.1 g/min, for example, 0.05 g/min. Time of bleaching the wafer 200 in TEMAH is set to a range of 30˜180 sec, for example, 60 sec. Here, the temperature of the heater 207 is set so that the temperature of the wafer 200 is in a range of 180˜250° C., for example, is 250° C. By supplying TEMAH into the processing chamber 201, TEMAH reacts with a surface part of an under layer on the wafer 200 and is chemically adsorbed.

(Step 2)

The first valve 243a of the first gas supply pipeline 232a is closed, and the supply of TEMAH is stopped.

Here, the APC valve 242 of the exhaust pipeline 231 is kept opened, the inside of the processing chamber 201 is exhausted to 20 Pa or less by the vacuum pump 246, and the remaining TEMAH gas is discharged from the processing chamber 201. In this case, by supplying an inert gas such as N₂ into the processing chamber 201, the discharge efficiency of the remaining TEMAH gas is improved even more.

(Step 3)

The second valve 243b of the second gas supply pipeline 232b and the fourth valve 243d of the second inert gas supply pipeline 234b are opened, and O₃ used as an oxidizing agent is flown to the second gas supply pipeline 232b, and an inert gas (N₂) used as a carrier gas is flown to the second inert gas supply pipeline 234b. The inert gas is flown from the second inert gas supply pipeline 234b, and a flow rate of the inert gas is adjusted by the fourth mass flow controller 241d. O₃ is flown from the second gas supply pipeline 232b, and a flow rate of O₃ is adjusted by the second mass flow controller 241b. O₃ is mixed with the inert gas, of which the flow rate is adjusted, and then exhausted through the exhaust pipeline 231 while being supplied into the processing chamber 201 through the second gas supply holes 248b of the second nozzle 233b. In this case, by properly controlling the APC valve 242, the pressure in the processing chamber 201 is maintained at 13.3˜1330 Pa, for example, 70 Pa. A supply amount of O₃ controlled by the second mass flow controller 241b is set to a range of 0.1˜10 slm, for example, 0.5 slm. Time of bleaching the wafer 200 in O₃ is set to a range of 1˜300 sec, for example, 40 sec. Here, the temperature of the heater 207 is set so that the temperature of the wafer 200 reaches a range of 180˜250° C., for example, 250° C., similarly to the case of supplying a TEMAH gas in the step 1. By supplying O₃, O₃ reacts with TEMAH chemically adsorbed on the surface of the wafer 200, and thus an HfO₂ film is formed on the wafer 200.

(Step 4)

After the film formation, the second valve 243b of the second gas supply pipeline 232b is closed, and supply of O₃ is stopped. Here, the APC valve 242 of the exhaust pipeline 231 is kept opened, the inside of the processing chamber 201 is exhausted to 20 Pa or less by the vacuum pump 246, and thus the remaining O₃ is discharged from the processing chamber 201. In this case, when an inert gas such as N₂ is supplied into the processing chamber 201, the discharge efficiency of the remaining O₃ is improved even more.

The above steps 1 to 4 are set as one cycle, and this cycle can be repeated a plurality of times to form an HfO₂ film with a predetermined thickness on the wafer 200.

After the HfO₂ film with a predetermined thickness is formed, the inside of the processing chamber 201 is vacuum-exhausted, and then, an inert gas such as N₂ is supplied into and simultaneously exhausted from the processing chamber 201 to purge the inside of the processing chamber 201. After purging the inside of the processing chamber 201, as the inside of the processing chamber 201 is substituted with an inert gas such as N₂, the pressure in the processing chamber 201 returns to the room temperature.

Then, a process for unloading the processed wafer 200 from the processing chamber 201 is executed. Specifically, as the seal cap 219 moves downward by the boat elevator 115, and the lower end of the manifold 209 is opened, the processed wafer 200 held by the boat 217 is unloaded from the lower end of the manifold 209 out of the process tube 203. Then, the processed wafer 200 is discharged from the boat 217.

Next, explanation will be given on a method of cleaning the inside of the processing chamber 201.

As the film formation is repeated, a film is deposited on an inner wall of the process tube 203 or the like. When a thickness of the film deposited on the inner wall reaches a predetermined thickness, cleaning is performed for the inside of the process tube 203. The cleaning is performed as follows.

First, the empty boat 217, that is, the boat 217 without charging the wafer 200 is moved upward by the boat elevator 115 and loaded into the processing chamber 201. In this state, the seal cap 219 seals the lower end of the manifold 209 via the O-ring 220b.

Next, the inside of the processing chamber 201 is vacuum-exhausted so as to reach a desired pressure (vacuum degree) by the vacuum pump 246. Here, the pressure in the processing chamber 201 is measured by the pressure sensor 245, and the APC valve 242 is feedback-controlled based on the measured pressure. Also, the inside of the processing chamber 201 is heated so as to reach a desired temperature by the heater 207. Here, power to the heater 207 is feedback-controlled based on the temperature information detected by the temperature sensor 263, so that the inside of the processing chamber 201 has a desired temperature distribution. In addition, the temperature control units 270a, 270b and 270c adjust the temperature of the metal member such as the manifold 209, the seal cap 219, the rotation shaft 255, the exhaust pipeline 231, and the APC valve 242 to a predetermined temperature, specifically to 550° C. or less. Next, the boat 217 is rotated by the rotating mechanism 254. Alternatively, the boat 217 may not be rotated.

Next, a cleaning gas including a halogen-based gas is supplied into the processing chamber 201 to remove materials including a high dielectric constant film deposited on the inside of the processing chamber 201.

Specifically, the fifth valve 243e of the third gas supply pipeline 232c is opened, and then a cleaning gas, that is, BCl₃ which is a halogen-based gas as an etching gas is flown to the third gas supply pipeline 232c. BCl₃ is flown from the third gas supply pipeline 232c, and a flow rate of BCl₃ is adjusted by the fifth mass flow controller 241e. BCl₃ is supplied from the first gas supply holes 248a of the first nozzle 233a into the processing chamber 201 through the first gas supply pipeline 232a.

The etching gas may be used at a concentration diluted with an inert gas such as N₂ from 100% to 20%, and when the etching gas is diluted, the third valve 243c of the first inert gas supply pipeline 234a is also opened. The inert gas is flown from the first inert gas supply pipeline 234a, and a flow rate of the inert gas is adjusted by the third mass flow controller 241c. BCl₃ is flown from the third gas supply pipeline 232c, and a flow rate of BCl₃ is adjusted by the fifth mass flow controller 241e. BCl₃ is mixed with the inert gas of which a flow rate is adjusted in the first gas supply pipeline 232a, and supplied into the processing chamber 210 through the first gas supply holes 248a of the first nozzle 233a.

Also, when O₂ is added as an additive of BCl₃ which is a halogen-based gas used as an etching gas, the sixth valve 243f of the fourth gas supply pipeline 232d is also opened. O₂ is flown from the fourth gas supply pipeline 232d, and a flow rate of O₂ is adjusted by the sixth mass flow controller 241f. O₂ is supplied from the second gas supply holes 248b into the processing chamber 201, through the second gas supply pipeline 232b. O₂ is mixed with BCl₃ or the inert gas in the processing chamber 201.

Here, while BCl₃ or O₂ may be successively supplied into the processing chamber 201, and simultaneously, may be successively exhausted from the exhaust pipeline 231. That is, in the state where the APC valve 242 is opened, while adjusting the pressure in the processing chamber 201 by the APC valve 242, BCl₃ or O₂ may be successively supplied into the processing chamber 201 and successively exhausted from the exhaust pipeline 231.

Also, supply of BCl₃ or O₂ into the processing chamber 201 and exhaust of BCl₃ or O₂ from the exhaust pipeline 231 may be intermittently performed. That is, the following steps C1 to C4 are set as one cycle, and a cleaning process may be performed by repeating this cycle a plurality of times.

(Step C1)

The APC valve 242 is opened and the inside of the processing chamber 201 is vacuum-exhausted. When the pressure in the processing chamber 201 reaches a first pressure, the APC valve 242 is closed. As such, the exhaust system is sealed.

(Step C2)

In this state, that is, in the state where the APC valve 242 is closed and the pressure in the processing chamber 201 becomes the first pressure, the fifth valve 243e and the sixth valve 243f are opened, and BCl₃ and O₂ are supplied into the processing chamber 201 for a predetermined time. Here, the third valve 243c may be opened, and an inert gas such as N₂ is supplied into the processing chamber 201 to dilute the etching gas. When the pressure in the processing chamber 201 becomes a second pressure, the fifth valve 243e and the sixth valve 243f are closed to stop supplying BCl₃ and O₂ into the processing chamber 201. Here, if the inert gas such as N₂ was being supplied, the third valve 243c is also closed to stop supplying the inert gas into the processing chamber 210. As such, the supply system is sealed. Here, all of the valves, that is, the first to sixth valves 243a, 243b, 243c, 243d, 243e and 243f and the APC valve 242 are in a closed state. That is, both the gas supply system and the exhaust system are sealed. Therefore, the inside of the processing chamber 201 is sealed, and BCl₃ and O₂ are enclosed in the processing chamber 201.

(Step 3)

This state, that is, the state where the gas supply system and the exhaust system are sealed to seal the processing chamber 201 and BCl₃ or O₂ are enclosed in the processing chamber 201 is maintained for a predetermined time.

(Step 4)

After a predetermined time passes, the APC valve 242 is opened, and the inside of the processing chamber 201 is vacuum-exhausted through the exhaust pipeline 231. Thereafter, the third valve 243c or the fourth valve 243d is opened, and an inert gas such as N₂ is exhausted from the exhaust pipeline 231 while supplying the inert gas into the processing chamber 201, thereby performing purge of the inside of the processing chamber 201.

The above steps C1 to C4 are set as one cycle, and this cycle is repeated predetermined times to perform a cleaning process by cycle etching. As such, in cleaning, a step of closing the APC valve 242 for a predetermined time and a step of opening the APC valve 242 for a predetermined time are repeated predetermined times. That is, opening and closing of the APC valve 242 are intermittently repeated predetermined times. According to the cleaning by cycle etching, by verifying an etching amount per one cycle, an etching amount can be controlled by the cycle number. Also, compared to a cleaning method by successively flowing an etching gas, the gas consumption can be removed.

BCl₃ or O₂ introduced into the processing chamber 201 is diffused entirely in the processing chamber 201, and contacts materials including a high dielectric film deposited on the inside of the processing chamber 201, that is, to an inner wall of the process tube 203 or the boat 217. Here, a thermochemical reaction occurs between the deposited materials and BCl₃ or O₂, and a reaction product is generated. The generated reaction product is exhausted out of the processing chamber 201 through the exhaust pipeline 231. As such, the deposited materials are removed (etched), and the cleaning of the inside of the processing chamber 201 is performed.

In the case of cleaning by successive supply•exhaust of a cleaning gas, when a predetermined cleaning time passes, the inside of the processing chamber 201 is vacuum-exhausted, and then, an inert gas such as N₂ is exhausted while supplying the inert gas into the processing chamber 201 to purge the inside of the processing chamber 201. After purging the inside of the processing chamber 201, the inside of the processing chamber 201 is substituted with the inert gas such as N₂.

In the case of cleaning by intermittent supply•exhaust of a cleaning gas, when the above cycle is performed predetermined times, the inside of the processing chamber 201 is vacuum-exhausted, and then, an inert gas such as N₂ is exhausted while supplying the inert gas into the processing chamber 201 to purge the inside of the processing chamber 201. After purging the inside of the processing chamber 201, the inside of the processing chamber 201 is substituted with the inert gas such as N₂.

Also, in the case of cleaning by successive supply•exhaust of a cleaning gas, a processing condition of cleaning, such as the processing temperature of 300˜600° C., the processing pressure of 13.3˜66500 Pa, a BCl₃ supply amount of 0.1˜10 slm, an O₂ supply amount of 0.1˜10 slm, and a cleaning time of 1˜100 min, is exemplified, and the cleaning is performed by constantly maintaining each cleaning condition at a value in each range.

In the case of cleaning by intermittent supply•exhaust of a cleaning gas, a processing condition of cleaning, such as the processing temperature of 300˜600° C., the first pressure of 1.33˜13300 Pa, the second pressure of 13.3˜66500 Pa, a BCl₃ supply amount of 0.11˜10 slm, an O₂ supply amount of 0.11˜10 slm, a gas supply time of 0.1˜15 min, a gas enclosing time of 0.1˜15 min, a gas exhausting time of 0.1˜10 min, the cycle number of 1˜100 times, is exemplified, and the cleaning is performed by constantly maintaining each cleaning condition at a value in each range.

Also, in the case of any cleaning, although a value ranging from 300 to 600° C. is exemplified as the temperature (processing temperature) in the processing chamber 201, the temperature of the metal members is set to a temperature of 550° C. or less, as explained above.

When the cleaning in the processing chamber 201 is completed, the film formation of a high dielectric constant film is performed again on the above-explained wafer 200. That is, the boat 217 with a plurality of sheets of wafers 200 charged is loaded into the processing chamber 201, the steps 1 to 4 are repeated to form a high dielectric constant film on the wafer 200, and then the boat 217 with the processed wafers 200 charged is unloaded from the processing chamber 201. Also, the film formation of the high dielectric film is repeated, and when the thickness of a film deposited on an inner wall of the process tube 203 or the like reaches a predetermined thickness, the above-explained cleaning is performed again.

### (5) Effects of the Current Embodiment

In the current embodiment, BCl₃ or O₂ supplied into the processing chamber 201 contacts the metal members installed in the processing chamber 201 or the gas flow route, that is, inner surfaces of the manifold 209, the exhaust pipeline 231, and the APC valve 242, and surfaces of the seal cap 219 and the rotation shaft 255. However, at least a surface of the metal member which is in contact with BCl₃ or O₂ is coated with the DLC film which has the erosion-resistance against a cleaning gas including BCl₃ or O₂, that is, a halogen-based gas other than a fluorine-based gas. As explained above, the DLC film, particularly the DLC film with sp³/(sp²+sp³) of at least 0.4 or more, is a material which is extremely difficult to react with the cleaning gas including a halogen-based gas such as BCl₃ or O₂, and difficult to be etched by the cleaning gas including a halogen-based gas such as BCl₃ or O₂. Therefore, when cleaning is performed by using the cleaning gas including a halogen-based gas without fluorine, the surface of the metal member can be sufficiently protected, and the erosion of the metal member and the meal contamination due to this erosion can be prevented.

In addition, in the case of performing intermittent supply•exhaust of a cleaning gas, that is, when the above steps C1 to C4 are set as one cycle and the cleaning is performed by repeating this cycle predetermined times, by verifying an etching amount per one cycle, the etching amount can be controlled by the cycle number. Also, compared to the case of cleaning by successive supply•exhaust of a cleaning gas, the gas consumption can be reduced.

### Another Embodiment of the Present Invention

In the above embodiment, although an HfO₂ film (hafnium oxide film) is formed as a high dielectric constant film, the present invention is not limited thereto. For example, the present invention can be applied to the case of forming a high dielectric constant film such as a ZrO₂ film (zirconium oxide film), an Al₂O₃ film (aluminum oxide film), a HfSiO film (hafnium silicate film), a ZrSiO film (zirconium silicate film), an AlSiO film (aluminum silicate film), a HfSiON film (hafnium silicate nitride film), a ZrSiON film (zirconium silicate nitride film), a HfAlO film (hafnium aluminate film), or a ZrAlO film (zirconium aluminate film).

Also, in the above embodiment, although a high dielectric constant film is formed by an ALD method, the present invention is not limited thereto. For example, the present invention can be applied to the case of forming a high dielectric constant film by a chemical vapor deposition (CVD) method, particularly a metal organic chemical vapor deposition (MOCVD) method.

Also, in the above embodiment, although the materials deposited on the inside of the processing chamber 201 are removed by a thermochemical reaction in the cleaning, the present invention is not limited thereto. For example, the present invention can be applied to the case of removing the materials deposited on the inside of the processing chamber 201 by a plasma chemical reaction.

Also, in the above embodiment, although BCl₃ is used as a halogen-based gas in the cleaning, the present invention is not limited thereto. For example, the present invention can be applied to the case of using halogen-based gases such as Cl₂, BBr₃, or Br₂.

Also, in the above embodiment, although O₂ is used as an additive in the cleaning, the present invention is not limited thereto. For example, the present invention can be applied to the case of using an oxygen-containing gas such as O₃, N₂O, or CO₂ as an additive.

Also, in the above embodiment, although an additive such as O₂ is added to a halogen-based gas such as BCl₃ in the cleaning, the present invention is not limited thereto. For example, the present invention can be applied to the case of cleaning by only a halogen-based gas without adding an additive.

According to the manufacturing method of the semiconductor device and the substrate processing apparatus in accordance with the present invention, the erosion of the metal members installed in the processing chamber can be suppressed.

### PREFERRED ASPECTS OF THE PRESENT INVENTION

Hereinafter, preferred aspects of the present invention will be explained.

According to an aspect of the present invention, there is provided a substrate processing apparatus, including: a processing chamber for performing a processing of forming a high dielectric constant film on a substrate; a processing gas supply system for supplying a processing gas into the processing chamber in order to form the high dielectric constant film; and a cleaning gas supply system for supplying a cleaning gas, which includes a halogen-based gas other than a fluorine-based gas, into the processing chamber in order to remove materials including the high dielectric constant film deposited on the inside of the processing chamber, wherein a metal member is installed inside the processing chamber, and a DLC film is formed on at least a part of a surface of the metal member where the cleaning gas contacts.

Preferably, the halogen-based gas other than a fluorine-based gas is a chlorine-based gas or a bromine-based gas.

Also, preferably, a composition ratio (sp³/(sp²+sp³)) of a diamond component (sp³) with respect to a graphite component (sp²) and the diamond component (sp³) of the DLC film is 0.4 or more

Also, preferably, the substrate processing apparatus further includes a temperature control unit for adjusting the temperature of the metal member to 550° C. or less when supplying the cleaning gas into the processing chamber.

Also, preferably, the halogen-based gas is a gas containing boron (B) and a halogen element other than fluorine. Also, preferably, the halogen-based gas is a gas containing boron (B) and chlorine (Cl). Also, preferably, the halogen-based gas is BCl₃.

Also, preferably, the cleaning gas further includes an oxygen-containing gas. Also, preferably, the cleaning gas further includes O₂. Also, preferably, the cleaning gas includes a gas containing boron (B) and a halogen element other than fluorine, and an oxygen-containing gas. Also, preferably, the cleaning gas includes a gas containing boron (B) and chlorine (Cl), and an oxygen-containing gas. Also, preferably, the cleaning gas includes BCl₃ and O₂.

Also, preferably, the high dielectric constant film is a film including at least one element of hafnium (Hf), zirconium (Zr), and aluminum (Al). Also, preferably, the high dielectric constant film is an oxide film including at least one element of hafnium (Hf), zirconium (Zr), and aluminum (Al).

Also, preferably, the metal member includes at least one element of nickel (ni), chrome (Cr), and iron (Fe).

According to another aspect of the present invention, there is provided a manufacturing method of a semiconductor device including: loading a substrate into a processing chamber in which a metal member is installed, wherein a DLC film is formed on a surface of the metal member; performing a process of forming a high dielectric constant film on the substrate by supplying a processing gas into the processing chamber; unloading the processed substrate from the processing chamber; and removing materials including the high dielectric constant film deposited on an inside of the processing chamber by supplying a cleaning gas, which comprises a halogen-based gas other than a fluorine-based gas, into the processing chamber.

Also preferably, at least in supplying the cleaning gas into the processing chamber, a surface temperature of the metal member is at 550° C. or less.

What is claimed is:

1. A substrate processing apparatus, comprising:
a processing chamber for performing a processing of forming a high dielectric constant film on a substrate;
a processing gas supply system for supplying a processing gas into the processing chamber in order to form the high dielectric constant film; and
a cleaning gas supply system for supplying a cleaning gas, which comprises a halogen-based gas other than a fluorine-based gas, into the processing chamber in order to remove materials including the high dielectric constant film deposited on an inside of the processing chamber,
wherein a metal member is installed inside the processing chamber, and a diamond-like carbon (DLC) film is formed on at least a part of a surface of the metal member where the cleaning gas contacts.

2. The substrate processing apparatus of claim 1, wherein the halogen-based gas is a chlorine-based gas or a bromine-based gas.

3. The substrate processing apparatus of claim 2, wherein a composition ratio (sp³/(sp²+sp³)) of a diamond component (sp³) with respect to a graphite component (sp²) and the diamond component (sp³) of the DLC film is 0.4 or more.

4. The substrate processing apparatus of claim 3, further comprising a temperature control unit for adjusting the temperature of the metal member to 550° C. or less when supplying the cleaning gas into the processing chamber.

5. The substrate processing apparatus of claim 1, wherein the halogen-based gas is a boron-containing gas.

6. The substrate processing apparatus of claim 1, wherein the halogen-based gas is BCl₃.

7. The substrate processing apparatus of claim 1, wherein the cleaning gas further comprises an oxygen-containing gas.

8. The substrate processing apparatus of claim 1, wherein the cleaning gas further comprises O₂.

9. The substrate processing apparatus of claim 1, wherein the halogen-based gas is a boron-containing gas, and the cleaning gas further comprises an oxygen-containing gas.

10. The substrate processing apparatus of claim 1, wherein the halogen-based gas is BCl₃, and the cleaning gas further comprises O₂.

11. The substrate processing apparatus of claim 1, wherein the metal member comprises at least one element of nickel, chrome, and iron.

12. A manufacturing method of a semiconductor device, comprising:
loading a substrate into a processing chamber in which a metal member is installed, wherein a DLC film is formed on a surface of the metal member;
performing a process of forming a high dielectric constant film on the substrate by supplying a processing gas into the processing chamber;
unloading the processed substrate from the processing chamber; and
removing materials including the high dielectric constant film deposited on an inside of the processing chamber by supplying a cleaning gas, which comprises a halogen-based gas other than a fluorine-based gas, into the processing chamber.
